(19) United States
(12) Patent Application Publication
(10) Pub. No.: US 2011/0155244 A1
(43) Pub. Date: Jun. 30, 2011

(54) SOLAR CELL AND METHOD FOR MANUFACTURING THE SAME

(75) Inventor: Dong-Chul SUH, Suwon-si (KR)

(73) Assignee: SAMSUNG ELECTRONICS CO., LTD., Suwon-si (KR)

(21) Appl. No.: 12/781,240

(22) Filed: May 17, 2010

(30) Foreign Application Priority Data
Dec. 30, 2009 (KR) 10-2009-0134604

(51) Int. Cl. H01L 31/0224; H01L 31/18

(52) U.S. Cl. 136/261; 438/98; 257/E31.124

(57) ABSTRACT

Disclosed is a solar cell including; a semiconductor substrate including a p-type layer and an n-type layer, a dielectric layer disposed on a surface of the semiconductor substrate, wherein the dielectric layer includes a plurality of penetrating parts, a first electrode electrically connected to the p-type layer of the semiconductor substrate, and a second electrode electrically connected to the n-type layer of the semiconductor substrate, wherein the first electrode includes; a fusion part which comprises a melt blend of a semiconductor material and a metal material and which is disposed within the plurality of penetrating parts of the dielectric layer, and a metal part which includes a metal material and is disposed on a surface of one side of the dielectric layer.

This application claims priority to Korean Patent Application No. 10-2009-0134604, filed on Dec. 30, 2009, and all the benefits accruing therefrom under 35 U.S.C. §119, the content of which in its entirety is herein incorporated by reference.

### BACKGROUND OF THE INVENTION

1. Field of the Invention

This disclosure relates to a solar cell and a method for manufacturing the same.

2. Description of the Related Art

A solar cell is a photoelectric conversion device that transforms photonic energy, typically solar energy, into electrical energy, and has attracted much attention as a renewable and pollution-free next generation energy source.

A solar cell typically includes p-type and n-type semiconductors and produces electrical energy by transferring electrons and holes to the n-type and p-type semiconductors, respectively, and then collecting electrons and holes in each electrode when an electron-hole pair (“EHP”) is produced by photonic energy absorbed in a photoactive layer inside the semiconductors.

Further, it is desirable for a solar cell to have as large an efficiency as possible for producing electrical energy from photonic energy. In order to increase the efficiency of a solar cell, it is beneficial to produce as many electron-hole pairs as possible, and to withdraw a resultant charge with minimal loss.

The charge may be lost due to recombination of the produced electrons and holes prior to their transport to an electrode. Accordingly, various methods of preventing such recombination have been suggested.

### BRIEF SUMMARY OF THE INVENTION

One aspect of this disclosure provides a high efficiency solar cell.

Another aspect of this disclosure provides a method of manufacturing the solar cell.

According to one aspect of this disclosure, an exemplary embodiment of a solar cell includes; a semiconductor substrate including a p-type layer and an n-type layer, a dielectric layer disposed on a surface of the semiconductor substrate, wherein the dielectric layer includes a plurality of penetrating parts, a first electrode electrically connected to the p-type layer of the semiconductor substrate, and a second electrode electrically connected to the n-type layer of the semiconductor substrate, wherein the first electrode includes; a fusion part which includes a melt blend of a semiconductor material and a metal material and which is disposed within the penetrating part of the dielectric layer; and a metal part which comprises a metal material and is disposed on a surface of the dielectric layer.

In addition, in one exemplary embodiment, the metal part is entirely made of a metal material in regions other than where it contacts the fusion part.

In one exemplary embodiment an amount of metal in a side of the fusion part adjacent to the semiconductor substrate may be different from an amount of metal in a side of the fusion part adjacent to the metal part. For example, in one exemplary embodiment, the amount of metal in the fusion part adjacent to the semiconductor substrate may range from about 0.01 wt % to about 0.1 wt % based on a total amount of the semiconductor material and the metal material in the fusion part adjacent to the semiconductor, and the amount of metal in the fusion part adjacent to the metal part may range from about 1 wt % to about 13 wt % based on a total amount of the semiconductor material and the metal material in the fusion part adjacent to the metal part.

In one exemplary embodiment, the melt blend of the semiconductor and the metal may be an alloy of the semiconductor material and the metal material. In one exemplary embodiment, the semiconductor material may include silicon (Si) or germanium (Ge), and the metal may include aluminum (Al), copper (Cu), or silver (Ag).

According to another exemplary embodiment of this disclosure, a method of manufacturing a solar cell includes; providing a semiconductor substrate including a p-type layer and an n-type layer, providing a dielectric layer on a surface of the semiconductor substrate, patterning the dielectric layer, providing a semiconductor particle layer including semiconductor particles on the semiconductor substrate between portions of the patterned dielectric layer, providing a first electrode electrically connected to the p-type layer of the semiconductor substrate on the dielectric layer, and providing a second electrode electrically connected to the n-type layer of the semiconductor substrate on a surface of the semiconductor substrate which opposes the surface where the dielectric layer is provided.

In one exemplary embodiment, the providing of the semiconductor particle layer may be performed by at least one of aerosol jet printing, screen printing, offset printing and gravure printing.

In one exemplary embodiment, a semiconductor material included in the semiconductor particle layer may be at least one of silicon (Si) and germanium (Ge). In addition, in one exemplary embodiment, the semiconductor material included in the semiconductor particle layer comprises substantially a same material as a semiconductor material included in the semiconductor substrate.

In one exemplary embodiment, the semiconductor particles included in the semiconductor particle layer may have a diameter of about 0.1 μm to about 30 μm, and the semiconductor particle layer may have a thickness of about 1 μm to about 40 μm.

In one exemplary embodiment, the providing of the first electrode may include; providing a conductive paste including a metal material and baking the conductive paste, wherein a semiconductor material included in the semiconductor particle layer may be alloyed with a metal material included in the conductive paste while baking the conductive paste. In addition, in one exemplary embodiment, while baking the conductive paste, the metal material included in the conductive paste may be alloyed with the semiconductor material included in the semiconductor particle layer and a semiconductor material included in the semiconductor substrate.

In one exemplary embodiment, the semiconductor particle layer may further include metal particles.

In the exemplary embodiment wherein the semiconductor particle layer includes semiconductor particles and metal particles, the semiconductor particle layer may include the metal particles at about 5 wt % to about 50 wt % based on a total amount of semiconductor particles and metal particles in the semiconductor layer.

In one exemplary embodiment, the metal particles included in the semiconductor particle layer may have a diameter of about 1 nm to about 10 μm.

In one exemplary embodiment, the metal particles and the semiconductor particles included in the semiconductor particle layer may be formed in a paste. In one exemplary embodiment, the providing of the semiconductor particle layer may be performed by at least one of aerosol jet printing, screen printing, offset printing and gravure printing.

In one exemplary embodiment, the providing of the first electrode may include providing a conductive paste including a metal material and baking the conductive paste. While baking the conductive paste, the semiconductor material included in the semiconductor particle layer may be alloyed with the metal material included in the semiconductor particle layer and the metal material included in the conductive paste.

In addition, while baking the conductive paste, the semiconductor material included in the semiconductor particle layer and the semiconductor material included in the semiconductor substrate may be alloyed with the metal material included in the semiconductor particle layer and the metal material included in the conductive paste.

Other aspects of this disclosure will be described in the following detailed description.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view of an exemplary embodiment of a solar cell according to the invention; and

FIGS. 2A to 2I are cross-sectional views that sequentially show an exemplary embodiment of a process of manufacturing the exemplary embodiment of a solar cell according to the invention.

FIG. 3 is a cross-sectional view of the conventional back electric field forming part.

### DETAILED DESCRIPTION OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

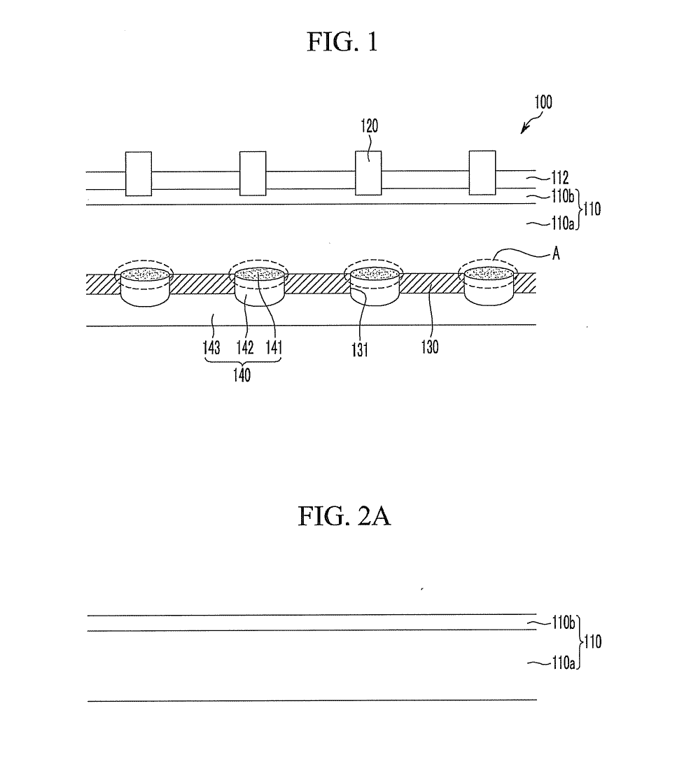

First, an exemplary embodiment of a solar cell according to this disclosure is described with reference to FIG. 1.

FIG. 1 is a cross-sectional view of a first exemplary embodiment of a solar cell 100.

Hereinafter, for the better understanding and ease of description, the relationship between an upper and lower position is described with respect to a center of a semiconductor substrate 110, but the present invention is not limited thereto.

Referring to FIG. 1, the exemplary embodiment of a solar cell 100 includes the semiconductor substrate 110, which in turn includes a lower semiconductor layer 110a and an upper semiconductor layer 110b.

The semiconductor substrate 110 may be made of crystalline silicon or a compound semiconductor or various other materials with similar characteristics. If the semiconductor substrate 110 is made of crystalline silicon, it may include, for example, a silicon wafer. One of the lower semiconductor layer 110a and the upper semiconductor layer 110b may be a semiconductor layer doped with a p-type impurity, and the other may be a semiconductor layer doped with an n-type impurity. The p-type impurity may include a Group III compound such as boron (B) or other materials with similar characteristics, and the n-type impurity may be a Group V compound such as phosphorus (P) or other materials with similar characteristics.

In one exemplary embodiment, the semiconductor substrate 110 may have a textured front, e.g., light source facing, surface. The semiconductor substrate 110 with the textured surface may have protrusions and depressions such as in a pyramid shape, or a porous structure such as a honeycomb structure or various other similar shapes. The semiconductor substrate 110 with the textured front surface may increase light absorption and reduce reflectance resulting in increased efficiency of the solar cell 100.

An insulation layer 112 is formed on the semiconductor substrate 110. The insulation layer 112 may be made of an insulating material that absorbs less light than the semiconductor substrate 110, and for example, it may include silicon nitride (SiNₓ), silicon oxide (SiO₂), titanium oxide (TiO₂), aluminum oxide (Al₂O₃), magnesium oxide (MgO), cerium oxide (CeO₂), other materials with similar characteristics, or a combination thereof. Exemplary embodiments include configurations wherein the insulation layer 112 may be formed as a single layer or a plurality of layers. The insulation layer 112 may have a thickness of, for example, about 200 Å to about 1500 Å.

The insulation layer 112 may act as an anti-reflective coating to decrease the reflectance of light on the surface of the solar cell 100 and increase the selectivity of absorption of a certain wavelength region in the semiconductor substrate 110, and simultaneously may improve the contact characteristics of the underlying silicon present on the surface of the semiconductor substrate 110 to increase the efficiency of the solar cell 100.

A plurality of front electrodes 120 are formed on the insulation layer 112. The front electrodes 120 extend along one direction of the substrate substantially in parallel to one another, and penetrate the insulation layer 112 to contact the upper semiconductor layer 110b. Exemplary embodiments of the front electrodes 120 may be made of a metal having low resistivity such as silver (Ag), and may be designed in a grid pattern considering shadowing loss and sheet resistance.

A front bus bar electrode (not shown) is formed on the front electrode 120. The bus bar electrode connects adjacent solar cells 100 (not shown) while assembling a plurality of solar cells into a solar array.

A dielectric layer 130 is formed on a lower surface of the lower semiconductor layer 110a of the semiconductor substrate 110. The dielectric layer 130 is patterned to provide a plurality of penetrating parts 131. The semiconductor substrate 110 contacts a rear electrode 140 through the penetrating parts 131.

The dielectric layer 130 prevents current leakage and recombination of charges to increase the efficiency of the solar cell 100 as will be described in detail below.

Exemplary embodiments of the dielectric layer 130 may include a material selected from the group consisting of an oxide, a nitride, an oxynitride, other materials with similar characteristics and a combination thereof; the oxide may include aluminum oxide (Al₂O₃), silicon oxide (SiO₂), titanium oxide (TiO₂ or TiO₄) or other materials with similar characteristics; the nitride may include silicon nitride (SiNₓ) or other materials with similar characteristics; and the oxynitride may include aluminum oxynitride (AlON), silicon oxynitride (SiON) or other materials with similar characteristics, but the dielectric layer 130 is not limited thereto.

In one exemplary embodiment, the dielectric layer 130 has a thickness of about 100 Å to about 2,000 Å, but its thickness is not limited thereto.

The rear electrode 140 is formed on the lower part of the dielectric layer 130. The rear electrode 140 may be made of an opaque metal such as aluminum (Al), and in one exemplary embodiment may have a thickness of about 2 μm to about 50 μm. The rear electrode 140 may also be made of copper (Cu), silver (Ag), and other materials with similar characteristics or combinations thereof.

The rear electrode 140 is disposed in the penetrating part 131 of the dielectric layer, and includes a fusion part (141, 142) including a melt blend of a semiconductor and a metal and a metal part 143 made of a metal and disposed on a surface of one side of the dielectric layer 130. In one exemplary embodiment, the metal part 143 is disposed on the entire surface of the one side of the dielectric layer 130. The melt blend of the semiconductor and the metal may be an alloy of the semiconductor and the metal, but is not limited thereto. The semiconductor may include silicon (Si) or germanium (Ge) and the metal may include aluminum (Al), copper (Cu), silver (Ag), and other materials with similar characteristics, or a combination thereof but they are not limited thereto.

The fusion part (141, 142) includes a plurality of back surface filled (“BSF”) electric field (A) forming parts 141 (p+ region) contacting the lower semiconductor layer 110a through the penetrating parts 131, and an alloy part 142 in which the semiconductor and the metal are alloyed.

In one exemplary embodiment, the back electric field (A) forming part 141 of the rear electrode 140 may be made of an alloy of silicon included in the lower semiconductor layer 110a and aluminum included in the rear electrode 140. In such an exemplary embodiment, the aluminum may act as a p-type impurity and provides an inner electric field therebetween, so as to prevent electrons from transporting to the rear side. Thereby, it may prevent the recombination and the loss of charges in the rear side, so as to increase the efficiency of the solar cell 100. The back electric field (A) forming part 141 may be discontinuously formed such that it may have a shape of, for example, a dot, a plate, a stripe or other similar configurations.

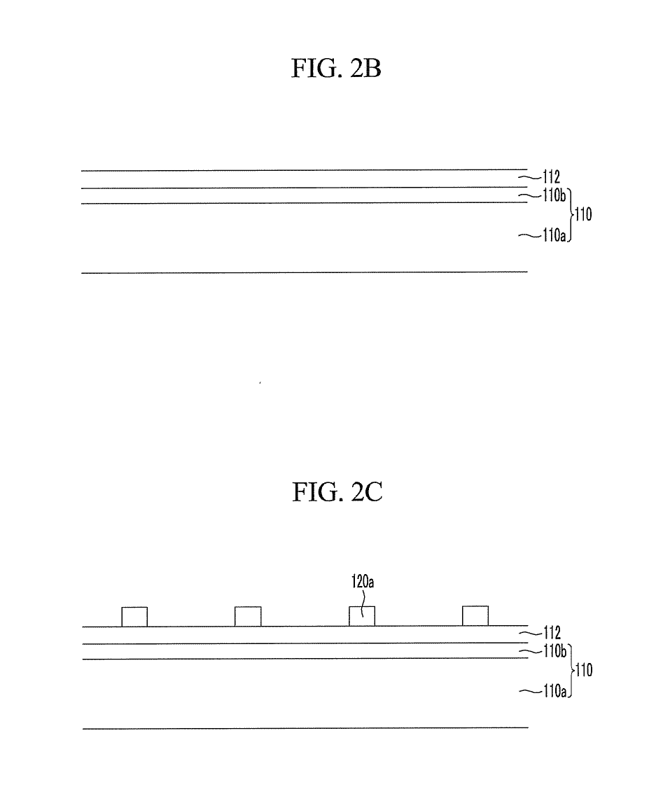

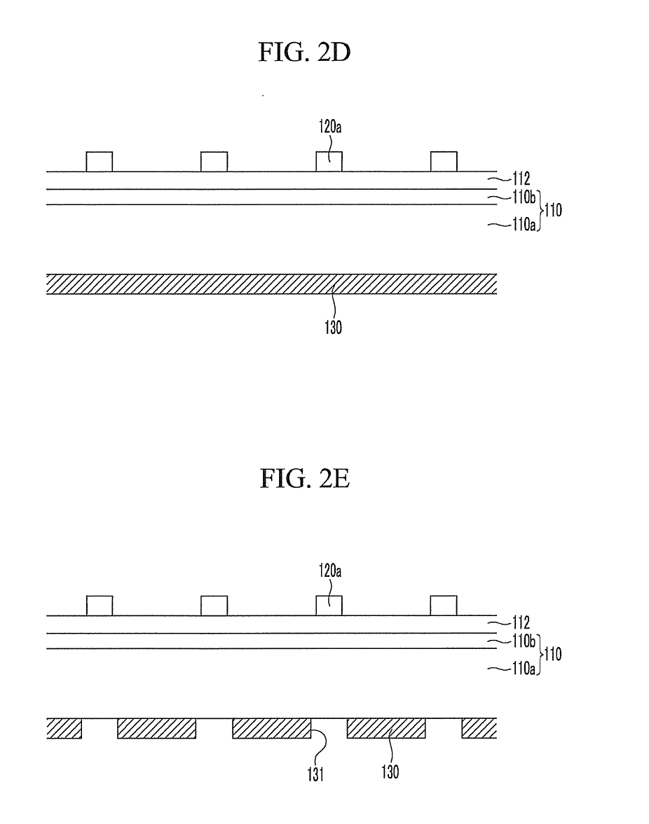

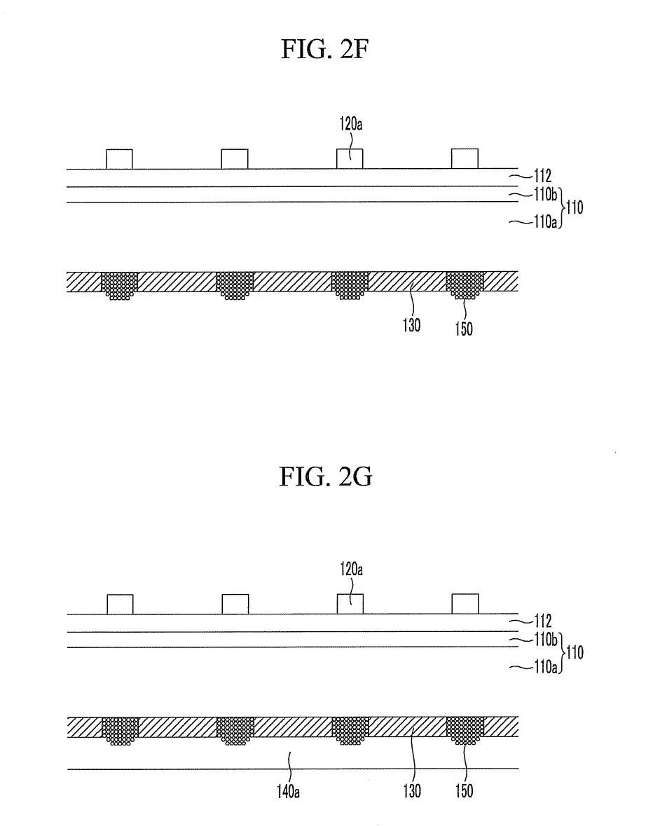

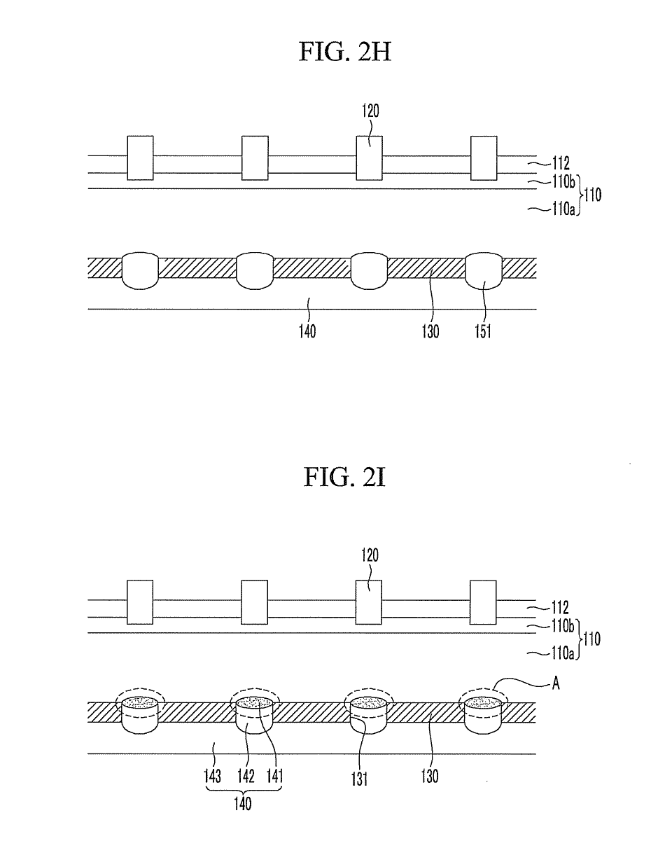

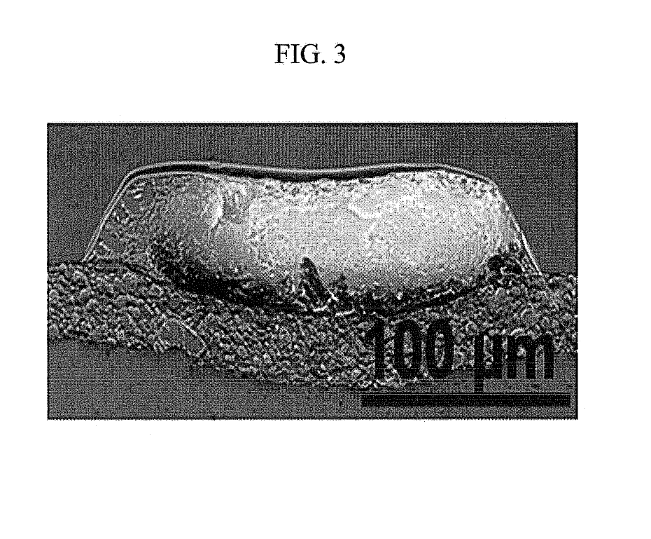

In one exemplary embodiment, the alloy part 142 of the rear electrode 140 may be made of, for example, an alloy of a semiconductor material such as silicon included in the lower semiconductor layer 110a or a semiconductor material including in a semiconductor particle layer 150 to be described in more detail below with respect to FIGS. 2A-2I, and aluminum included in the rear electrode 140. The aluminum included in the rear electrode 140 reacts with the lower semiconductor layer 110a and/or the semiconductor particle layer 150 to form an alloy, so it prevents the aluminum included in the rear electrode 140 from deeply penetrating into the lower semiconductor layer 110a. Thereby, the back electric field (A) forming part 141 may have a smooth curved surface at the interface with the lower semiconductor layer 110a. The smooth curved surface may be the shape of half the surface of an ellipse since voids are not formed in the back electric field (A) forming part 141. On the other hand, the conventional back electric field forming part had voids. For reference, FIG. 3 is a cross-sectional view of the conventional back electric field forming part.

Also, parasitic shunting may be prevented and the efficiency of the solar cell 100 may be improved.

The metal amount of the back electric field (A) forming part 141, i.e., the metallic composition of the back electric field (A) forming part 141, may be different from the metal amount of the alloy part 142, i.e. the metallic composition of the alloy part 142. For example, the metal amount of the back electric field (A) forming part 141 may range from about 0.01 wt % to about 0.1 wt % based on the total amount of the semiconductor material and the metal material in the back electric field (A) forming part 141, and the metal amount of the alloy part 142 may range from about 1 wt % to about 13 wt % based on the total amount of the semiconductor material and the metal material in the alloy part 142. When the metal amounts of the back electric field (A) forming part 141 and the alloy part 142 are within the above described ranges, respectively, it is stoichiometrically stable and maintains the equilibrium state, so the physical properties of the back electric field (A) forming part 141 and the alloy part 142 may be maintained without being changed.

Therefore, the recombination of charges is prevented by providing a patterned dielectric layer 130 in the lower part of the semiconductor substrate 110, and a part of the rear electrode 140 contacts the semiconductor substrate to provide a back electric field (A) forming part 141 having a smooth curved surface, so it is possible to prevent the parasitic shunting and to a generate back electric field (A). Thereby, the patterned dielectric layer 130 and the rear electrode 140 may increase the efficiency of the solar cell 100.

In addition, since the metal part 143 of the rear electrode 140 is provided on substantially the entire surface of the lower part of the dielectric layer 130, it reflects light passed through the semiconductor substrate 110 back into the semiconductor substrate 110 to prevent light loss, so as to increase the efficiency of the solar cell 100. The metal part 143 is made of a metal and does not include the semiconductor material except possibly in the part contacting the fusion part (141, 142).

A rear bus bar electrode (not shown) is provided in electrical contact with, e.g., on the lower part of, the rear electrode 140. The rear bus bar electrode is provided to connect adjacent solar cells (not shown) while assembling a plurality of solar cells into a solar array. The rear bus bar electrode may be made of, for example, silver (Ag), aluminum (Al), copper (Cu), other materials with similar characteristics, or a combination thereof.

Hereinafter, an exemplary embodiment of a method of manufacturing the exemplary embodiment of a solar cell according to this disclosure is described with reference to FIGS. 2A to FIG. 2I along with FIG. 1.

FIGS. 2A to 2I are cross-sectional views that sequentially show an exemplary embodiment of a process of manufacturing an exemplary embodiment of a solar cell.

First, a semiconductor substrate 110, for example a silicon wafer, is provided. In one exemplary embodiment, the semiconductor substrate 110 may be doped with a p-type impurity, for example.

Then, in at least one exemplary embodiment the semiconductor substrate 110 may be subjected to a surface texturing treatment. The surface-texturing treatment may be performed by a wet method using a strong acid such as nitric acid and hydrofluoric acid or other material with similar characteristics or strong base such as sodium hydroxide or other material with similar characteristics, or by a dry method using plasma.

Then, in the exemplary embodiment wherein the semiconductor substrate 110 is pre-doped with a p-type impurity, referring to FIG. 2A, the semiconductor substrate 110 is doped with an n-type impurity. The n-type impurity may be doped by diffusing POCl₃ or H₃PO₄ or other material with similar characteristics at a high temperature, for example about 400° C. to about 900° C.

The semiconductor substrate 110 includes a lower semiconductor layer 110a and an upper semiconductor layer 110b doped with different impurities.

As shown in FIG. 2B, an insulation layer 112 is formed on the semiconductor substrate 110. The insulation layer 112 may be formed with, for example, silicon nitride, by plasma enhanced chemical vapor deposition (“PECVD”) or other similar method.

As shown in FIG. 2C, a front electrode conductive paste 120a is formed on the insulation layer 112. In the present exemplary embodiment, the front electrode conductive paste 120a is formed by a screen printing method. The screen printing method includes coating a front electrode conductive paste 120a including metal powder such as silver (Ag) on the position where the front electrodes 120 are to be formed, and drying the same. However, the formation process of the front electrode 120 is not limited thereto, and includes inkjet printing, press printing or other similar methods.

The front electrode conductive paste 120a is dried. The drying may be performed, for example, at about 150° C. to about 400° C.

A front bus bar electrode (not shown) may be formed on the front electrode conductive paste 120a.

Then, referring to FIG. 2D, the dielectric layer 130 is formed on the lower surface of the semiconductor substrate 110, and it may include, for example, an oxide such as aluminum oxide (Al₂O₃), silicon oxide (SiO₂), titanium oxide (TiO₂ or TiO₄) or other material with similar characteristics; a nitride such as silicon nitride (SiNₓ) or other material with similar characteristics; an oxynitride such as aluminum oxynitride (AlON) and silicon oxynitride (SiON) or other material with similar characteristics; or a combination thereof. The dielectric layer 130 may be formed by a method such as vacuum deposition, spin coating, chemical vapor deposition, atomic layer deposition, sputtering, or other similar methods.

As shown in FIG. 2E, the dielectric layer 130 is patterned to provide a plurality of penetrating parts 131. The penetrating parts 131 may have a shape of a dot, a plate, a stripe or various other arrangements. The patterning may be performed by patterning using a laser, patterning using an etching paste, photolithography, dry etching, or other similar methods, but is not limited thereto.

As shown in FIG. 2F, a semiconductor particle layer 150 is provided in the penetrating part 131. The semiconductor particle layer 150 may be obtained by aerosol jet printing, screen printing, offset printing, gravure printing, or other similar methods, but is not limited thereto as long as it provides a semiconductor particle layer 150 in the penetrating parts 131.

The semiconductor included in the semiconductor particle layer 150 may include silicon (Si), germanium (Ge) or other materials with similar characteristics.

In addition, in one exemplary embodiment the semiconductor material included in the semiconductor particle layer 150 may be of the same type and composition as the semiconductor included in the lower semiconductor layer 110a. The metal included in a rear electrode conductive paste 140a, to be described in more detail below, may be alloyed with the semiconductor material included in the semiconductor particle layer 150 as well as the semiconductor material included in the lower semiconductor layer 110a while forming a rear electrode 140. This method may prevent the metal included in the rear electrode conductive paste 150a from reacting to a large degree with the semiconductor included in the lower semiconductor layer 110a, e.g., the semiconductor particle layer 150 serves as a buffer between the rear electrode conductive paste 140a and the semiconductor layer 110a. Thus, the back electric field (A) forming part 141 is penetrated into the semiconductor substrate side only to a shallow depth, and may thus alleviate asymmetry of the bottom surface and the upper side surface (semiconductor substrate side) of the back electric field (A) forming part penetrated into the semiconductor substrate, and suppress the parasitic shunting thereof.

In addition, since the rear electrode 140 is provided after forming the semiconductor particle layer 150, it may prevent side effects which may be caused if the semiconductor material were mixed together with the rear electrode conductive paste 140a. In an arrangement wherein the semiconductor material is mixed with the rear electrode conductive paste 140a, the semiconductor material may be reacted with the rear electrode conductive paste 140a to generate impurities in the fusion part (141, 142), for example a region other than the back electric field forming part 141, so the resistance of the rear electrode would be increased so as to decrease the fill factor (“FF”) of the solar cell. The present invention thereby avoids these consequences by forming the rear electrode 140 subsequently to forming the semiconductor particle layer 150.

In one exemplary embodiment, the semiconductor particles included in the semiconductor particle layer 150 may have a diameter of about 0.1 μm to about 30 μm. When the semiconductor particles included in the semiconductor particle layer 150 have a diameter within the above-described range, the rear electrode conductive paste 140a easily penetrates between the semiconductor particles while forming a rear electrode 140. Thereby, it is possible to improve the reactivity between the metal material included in the rear electrode conductive paste 140a and the semiconductor particles included in the semiconductor particle layer 150. During the baking process to provide the rear electrode 140, the semiconductor particles included in the semiconductor particle layer 150 are well reacted with the metal material included in the rear electrode conductive paste 140a to provide an alloy thereof, and then the alloy may electrically connect the rear electrode 140 to the lower semiconductor substrate 110a and effectively provide a back electric field (A) forming part 141 having a smooth curved surface so as to suppress generation of the parasitic shunting. For example, in one exemplary embodiment the semiconductor particle included in the semiconductor particle layer 150 may have a diameter of about 3 μm to about 10 μm.

Exemplary embodiments of the semiconductor particle layer 150 may include semiconductor particles having a uniform diameter, or may include semiconductor particles having different diameters.

Although not shown in FIG. 2F, the semiconductor particle layer 150 may further include metal particles mixed together with the semiconductor particles. In one exemplary embodiment, the metal particles may be composed of substantially the same material as the rear electrode 140. For example, the metal particles may include aluminum (Al), copper (Cu), silver (Ag), or other materials with similar characteristics, but are not limited thereto.

When the semiconductor particle layer 150 further includes the metal particles, the semiconductor particles may be present adjacent to the metal particles in the semiconductor particle layer 150. During the baking process to provide a rear electrode, the semiconductor particles included in the semiconductor particle layer 150 are well reacted with the metal particles included in the semiconductor particle layer 150 to provide an alloy thereof. In addition, the metal included in the rear electrode conductive paste 140a may also be reacted with the semiconductor particles included in the semiconductor particle layer 150 to provide an alloy thereof. Thereby, the metal particles included in the semiconductor particle layer 150 and the metal included in the rear electrode conductive paste 140a may have a decreased amount of reaction with the semiconductor included in the lower semiconductor layer 110a. Thereby, the depth to which the back electric field (A) forming part 141 which is generated together while forming the rear electrode 140 is penetrated into the lower semiconductor substrate 110a may be made to be shallow, thereby alleviating an asymmetry of the lower surface and the upper side (semiconductor substrate side) surface of the back electric field (A) forming part 141 penetrated into the semiconductor substrate, and suppress generation of the parasitic shunting. Specifically, since the penetrating part 131 is already at least partially filed with material, e.g., a semiconducting material or a semiconducting material and metal particles, the rear electrode conductive paste 140a will not penetrate as far into the penetrating part 131 as it would in the absence of such material filling the penetrating part 131. Thus, a smooth surface may be formed between the alloy of the semiconducting material and the metal material of the rear electrode conductive past 140a and the lower semiconductor layer 110a, and a lower surface of the resulting rear electrode 140 may have a substantially planar surface without depressions or grooves corresponding to the penetrating parts 131.

When the semiconductor particle layer 150 includes semiconductor particles and metal particles, the semiconductor particle layer 150 may include the metal particles at about 5 wt % to about 50 wt % based on a total amount of material in the semiconductor particles and the metal particles. When the semiconductor particle layer 150 includes the metal particles within the above-described range, all semiconductor particles included in the semiconductor particle layer 150 may be reacted and alloyed. Thereby, it is possible to provide a back electric field (A) forming part 141 having good quality as long as the resistance of the rear electrode 140 is not increased.

In one exemplary embodiment, the metal particles included in the semiconductor particle layer 150 may have a diameter of about 1 nm to about 10 μm. When the metal particles included in the semiconductor particle layer 150 have a diameter within the above-described range, the semiconductor particles are uniformly mixed with the metal particles. Thereby, the reactivity between the semiconductor particles included in the semiconductor particle layer 150 and the metal particles included in the semiconductor particle layer 150 may be effectively improved. Thereafter, when the semiconductor particles included in the semiconductor particle layer 150 are well reacted with the metal particles included in the semiconductor particle layer 150 to provide an alloy during the baking process to provide a rear electrode 140, they may electrically connect the rear electrode 140 to the semiconductor substrate 110 and also effectively obtain a back electric field (A) forming part 141 having a smooth curved surface, so it is possible to prevent generation of the parasitic shunting. For example, in one exemplary embodiment the metal particles included in the semiconductor particle layer 150 may have a diameter of about 10 nm to about 10 μm.

Exemplary embodiments of the semiconductor particle layer 150 may have metal particles having a uniform diameter or metal particles having different diameters.

In one exemplary embodiment, the metal particles and the semiconductor particles included in the semiconductor particle layer 150 may be formed in a paste. In such an exemplary embodiment, the providing of a semiconductor particle layer 150 may be performed by aerosol jet printing, screen printing, offset printing, gravure printing, or other similar methods, but is not limited thereto.

In one exemplary embodiment, the semiconductor particle layer 150 may have a thickness of about 1 μm to about 40 μm. When the semiconductor particle layer 150 has a thickness within the above-described range, it may provide a back electric field region without leaving unreacted semiconductor particles therein. For example, in one exemplary embodiment the semiconductor particle layer 150 may have a thickness of about 2 μm to about 20 μm. In another exemplary embodiment the semiconductor particle layer 150 may have a thickness of about 4 μm to about 10 μm.

Then, as shown in FIG. 2G, the rear electrode conductive paste 140a is provided on the lower part of dielectric layer 130 to cover substantially the entire surface of the dielectric layer 130 and the semiconductor particle layer 150. The rear electrode conductive paste 140a may be formed by a screen printing method or other similar method. The screen printing method includes coating the rear electrode conductive paste 140a including a metal powder such as aluminum (Al) on substantially the entire surface of the lower part of dielectric layer 130 and drying the same. However, the method of forming the rear electrode conductive paste 140a is not limited thereto, and it may be provided by Inkjet printing, press printing, or other similar method.

When the rear electrode conductive paste 140a is obtained in accordance with the above-described method, the rear electrode conductive paste 140a is permeated between particles included in the semiconductor particle layer 150 to contact the lower semiconductor layer 110a.

Then the rear electrode conductive paste 140a is dried. In one exemplary embodiment, the drying may be performed, for example, at about 150° C. to about 400° C.

Then, as shown in FIG. 2H, the front electrode conductive paste 120a and the rear electrode conductive paste 140a are baked. The front electrode conductive paste 120a and the rear electrode conductive paste 140a may include a metal powder, a glass frit, an organic vehicle or other similar materials.

The front electrode conductive paste 120a and the rear electrode conductive paste 140a respectively form a front electrode 120 and a rear electrode 140 by penetrating the metal powder into the upper semiconductor layer 110b and the lower semiconductor layer 110a, respectively, during the baking process. The rear electrode conductive paste 140a is melted with the semiconductor included in the semiconductor particle layer 150 and the semiconductor included in the lower semiconductor layer 110a, or the semiconductor and the metal included in the semiconductor particle layer 150 and the semiconductor included in the lower semiconductor layer 110a, are melted to provide a precursor 151 of the back electric field (A) forming part 141. Thereby, the method of forming the precursor 151 may prevent the rear electrode conductive paste 140a from reacting to a greater degree with the semiconductor material included in the lower semiconductor layer 110a and prevent the conductive paste 140a from deeply penetrating into the lower semiconductor layer 110a side beyond the interface of the precursor 151 of the back electric field (A) forming part 141 and the lower semiconductor layer 110a.

The baking may be performed at a higher temperature than the melting point of the metal powder, for example, at a temperature of about 570° C. to about 750° C. In one exemplary embodiment, the baking may be performed at a temperature of about 670° C. to about 730° C.

Referring to FIG. 2I, the melted precursor of the back electric field (A) forming part 151 is cooled. After the cooling process, the precursor of the back electric field (A) forming part 151 may provide a back electric field (BSF) (A) forming part 141 and an alloy part 142 in which the semiconductor is alloyed with the metal. A plurality of back electric field (A) forming parts 141 contacting the lower semiconductor layer 110a may be formed to penetrate into the lower semiconductor layer 110a in a smooth curved surface. Thereby, it is possible to alleviate the asymmetry of the lower surface and the upper side (semiconductor substrate side) surface of the back electric field (A) forming part 141 penetrated into the semiconductor substrate 110 and to suppress generating the parasitic shunting.

In one exemplary embodiment, the cooling may be performed at a speed of about 30° C./min to about 100° C./min. In one exemplary embodiment, for example, the cooling may be performed at a speed of about 50° C./min to about 70° C./min.

Subsequently, a rear bus bar electrode (not shown) may be provided on the lower part of the rear electrode 140.

According to one embodiment, the dielectric layer 130 is provided on the lower semiconductor layer 110a of the semiconductor substrate 110 to prevent the recombination of charges, and the semiconductor particle layer 150 is provided on the semiconductor substrate 110 between the patterned dielectric layers 130 and then baked and cooled to provide a back electric field (A) forming part 141 which shallowly penetrates into the lower semiconductor layer, so it is possible to prevent parasitic shunting. Thereby, it may enhance the efficiency of the solar cell 100.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a semiconductor substrate comprising a p-type layer and an n-type layer;
a dielectric layer disposed on a surface of the semiconductor substrate, wherein the dielectric layer includes a plurality of penetrating parts;
a first electrode electrically connected to the p-type layer of the semiconductor substrate; and
a second electrode electrically connected to the n-type layer of the semiconductor substrate,
wherein the first electrode comprises:
a fusion part which comprises a melt blend of a semiconductor material and a metal material and which is disposed within the plurality of penetrating parts of the dielectric layer; and
a metal part which comprises a metal material and is disposed on a surface of the dielectric layer.

2. The solar cell of claim 1, wherein the metal part is entirely made of a metal material in regions other than where it contacts the fusion part.

3. The solar cell of claim 1, wherein an amount of metal in a side of the fusion part adjacent to the semiconductor substrate is different from an amount of metal in a side of the fusion part adjacent to the metal part.

4. The solar cell of claim 3, wherein the amount of metal in the fusion part adjacent to the semiconductor substrate ranges from about 0.01 wt % to about 0.1 wt % based on a total amount of the semiconductor material and the metal material in the fusion part adjacent to the semiconductor, and the amount of metal in the fusion part adjacent to the metal part ranges from about 1 wt % to about 13 wt % based on a total amount of the semiconductor material and the metal material in the fusion part adjacent to the metal part.

5. The solar cell of claim 1, wherein the melt blend of the semiconductor material and the metal material is an alloy of the semiconductor material and the metal material.

6. The solar cell of claim 1, wherein the semiconductor material includes at least one of silicon and germanium, and the metal material includes at least one of aluminum, copper and silver.

7. A method of manufacturing a solar cell, the method comprising:
providing a semiconductor substrate comprising a p-type layer and an n-type layer;
providing a dielectric layer on a surface of the semiconductor substrate;
patterning the dielectric layer;
providing a semiconductor particle layer comprising semiconductor particles on the semiconductor substrate between portions of the patterned dielectric layer;
providing a first electrode electrically connected to the p-type layer of the semiconductor substrate on the dielectric layer; and
providing a second electrode electrically connected to the n-type layer of the semiconductor substrate on a surface of the semiconductor substrate which opposes the surface where the dielectric layer is provided.

8. The method of claim 7, wherein the providing of the semiconductor particle layer is performed by at least one of aerosol jet printing, screen printing, offset printing and gravure printing.

9. The method of claim 7, wherein a semiconductor material included in the semiconductor particle layer comprises substantially a same material as a semiconductor material included in the semiconductor substrate.

10. The method of claim 7, wherein the semiconductor particles included in the semiconductor particle layer have a diameter of about 0.1 μm to about 30 μm.

11. The method of claim 7, wherein the semiconductor particle layer has a thickness of about 1 μm to about 40 μm.

12. The method of claim 7, wherein the providing of the first electrode comprises:
providing a conductive paste comprising a metal material; and
baking the conductive paste,
wherein a semiconductor material included in the semiconductor particle layer is alloyed with a metal material included in the conductive paste while baking the conductive paste.

13. The method of claim 12, wherein the metal material included in the conductive paste is alloyed with the semiconductor material included in the semiconductor particle layer and a semiconductor material included in the semiconductor substrate while baking the conductive paste.

14. The method of claim 7, wherein the semiconductor particle layer further comprises metal particles.

15. The method of claim 14, wherein the semiconductor particle layer comprises the metal particles at about 5 wt % to about 50 wt % based on a total amount of the semiconductor particles and the metal particles in the semiconductor particle layer.

16. The method of claim 14, wherein the metal particles included in the semiconductor particle layer have a diameter of about 1 nm to about 10 μm.

17. The method of claim 14, wherein the metal particles and the semiconductor particles are included in the semiconductor particle layer in the form of a paste.

18. The method of claim 14, wherein the providing of the semiconductor particle layer is performed by at least one of aerosol jet printing, screen printing, offset printing and gravure printing.

19. The method of claim 14, wherein the providing of the first electrode comprises:
providing a conductive paste including a metal material; and
baking the conductive paste,
wherein a semiconductor material included in the semiconductor particle layer is alloyed with the metal material included in the semiconductor particle layer and the metal material included in the conductive paste while baking the conductive paste.

20. The method of claim 19, wherein the semiconductor material included in the semiconductor particle layer and the semiconductor material included in the semiconductor substrate are alloyed with the metal material included in the semiconductor particle layer and the metal material included in the conductive paste while baking the conductive paste.
